(19) United States
(12) Patent Application Publication
(10) Pub. No.: US 2024/0094266 A1
(43) Pub. Date: Mar. 21, 2024

(54) INFORMATION PROCESSING DEVICE, INFORMATION PROCESSING METHOD, AND COMPUTER PROGRAM

(71) Applicant: Premo Inc., Tokyo (JP)

(72) Inventors: Hidenori TSUJI, Tokyo (JP); Junta MIYAMOTO, Tokyo (JP)

(21) Appl. No.: 18/523,896

(22) Filed: Nov. 30, 2023

Related U.S. Application Data
(63) Continuation of application No. PCT/JP2023/009176, filed on Mar. 9, 2023.

(30) Foreign Application Priority Data
Mar. 9, 2022 (JP) 2022-036120

(51) Int. Cl. G01R 19/165; G01R 19/145

(52) U.S. Cl. CPC G01R 19/165; G01R 19/145

(57) ABSTRACT

To enable necessary information to be obtained from a sensor when necessary. An information processing device includes a processing unit including a memory, a sensing unit, a condition storage unit configured to store a condition for outputting a situation value indicating a state according to a situation in which the information processing device is disposed, a determination unit configured to determine whether the condition is satisfied, a situation value calculation unit configured to calculate the situation value based on a measured value acquired by the sensing unit, and an output unit configured to output the situation value when the condition is satisfied.

### FIELD

The present invention relates to an information processing device, an information processing method, and a computer program.

### BACKGROUND

A system that relays data from sensor nodes by a gateway device is known (see Patent Literature 1).

### CITATION LIST

### Patent Literature

Patent Literature 1: Japanese Patent Application Laid-open No. 2021-57740

### SUMMARY

### Technical Problem

In the system disclosed in Patent Literature 1, since data from sensor nodes are transmitted to a gateway and stored in a cloud, the cloud side needs to continuously monitor the data.

The present invention has been made in view of this background, and an object of the present invention is to provide a technology that enables necessary information to be obtained from a sensor when necessary.

### Solution to Problem

A main invention to solve the above problem is an information processing device including a processing unit including a memory, a sensing unit, a condition storage unit configured to store a condition for outputting a situation value indicating a state according to a situation in which the information processing device is disposed, a determination unit configured to determine whether the condition is satisfied, a situation value calculation unit configured to calculate the situation value based on a measured value acquired by the sensing unit, and an output unit configured to output the situation value when the condition is satisfied.

Other issues disclosed in the present application and methods for solving the problems will be clarified in the embodiments of the invention section and in the drawings.

### Advantageous Effects of Invention

According to the present invention, necessary information can be obtained from a sensor when necessary.

### BRIEF DESCRIPTION OF DRAWINGS

FIG. 1 is a diagram illustrating an example of the overall configuration of an information processing system according to an embodiment of the present invention.

FIG. 2 illustrates an example of the hardware configuration of an information processing device 1 that is an embodiment of the present invention.

FIG. 3 is a block diagram illustrating the functional configuration of the information processing device 1.

FIG. 4 is a diagram for explaining an operation of the information processing device 1 of the present embodiment.

### DESCRIPTION OF EMBODIMENTS

<Summary of Invention>

Details of embodiments of the present invention are listed and described. The invention includes, for example, the following configurations.

### [Item 1]

An information processing device including:
a processing unit including a memory;
a sensing unit;
a condition storage unit configured to store a condition for outputting a situation value indicating a state according to a situation in which the information processing device is disposed;
a determination unit configured to determine whether the condition is satisfied;
a situation value calculation unit configured to calculate the situation value based on a measured value acquired by the sensing unit; and
an output unit configured to output the situation value when the condition is satisfied.

### [Item 2]

The information processing device according to item 1, further including
a condition setting unit configured to receive the condition from outside, and to set the condition in the condition storage unit.

### [Item 3]

The information processing device according to item 1, further including
a measured value storage unit configured to store a history of the measured value, in which
the situation value calculation unit reads the measured value from the measured value storage unit, and calculates the situation value based on the read measured value.

### [Item 4]

The information processing device according to item 3, in which the situation value calculation unit calculates the situation value based on a first measured value corresponding to a first period and a second measured value corresponding to a second period having a length different from a length of the first period.

### [Item 5]

The information processing device according to item 1, in which
the sensing unit measures a first measured value at a first cycle and measures a second measured value at a second cycle shorter than the first cycle, and
the situation value calculation unit calculates the situation value based on the first and second measured values.

### [Item 6]

The information processing device according to item 1, further including:
a situation value storage unit configured to store a history of the calculated situation value; and
a reception unit configured to receive an external request, in which
the output unit reads the situation value corresponding to a period designated in the request from the situation value storage unit, and outputs the read situation value.

### [Item 7]

The information processing device according to item 6, in which
the situation value calculation unit calculates a second situation value based on the measured value acquired by the sensing unit and a first situation value stored in the situation value storage unit, and
the output unit outputs the second situation value.

### [Item 8]

The information processing device according to item 1, further including:
a measured value storage unit configured to store a history of the measured value; and
a reception unit configured to receive an external request, in which
the situation value calculation unit reads the measured value corresponding to a period designated in the request from the measured value storage unit, and calculates the situation value based on the read measured value.

### [Item 9]

The information processing device according to item 8, in which the situation value calculation unit extracts the measured value at different cycles depending on a length of the period from the measured value storage unit, and calculates the situation value based on the extracted measured value.

### [Item 10]

The information processing device according to item 1, in which
the condition storage unit stores specifying information that specifies the measured value to be calculated in association with the condition, and
the information processing device further includes:
   a measured value storage unit configured to store a history of the measured value; and
   a situation value calculation unit configured to read the measured value specified by the specifying information corresponding to the satisfied condition from the measured value storage unit, and to calculate the situation value based on the read measured value.

### [Item 11]

The information processing device according to item 1, further including
a logic storage unit configured to store a logic for calculating the situation value based on the measured value, in which
the condition storage unit stores, in association with the condition, calculation target specifying information that specifies the measured value to be calculated and logic specifying information that specifies the logic, and
the information processing device further includes:
   a measured value storage unit configured to store a history of the measured value; and
   a situation value calculation unit configured to calculate the situation value by giving the measured value specified by the calculation target specifying information corresponding to the satisfied condition to the logic specified by the logic specifying information corresponding to the satisfied condition.

### [Item 12]

The information processing device according to any one of items 1 to 11, in which the output unit outputs the situation value to outside of the information processing device via the sensing unit.

### [Item 13]

The information processing device according to any one of items 1 to 11, in which a signal is received from outside of the information processing device via the sensing unit.

### [Item 14]

An information processing method performed by an information processing device, the information processing method including:
a step of storing a condition for outputting a situation value indicating a state according to a situation in which the information processing device is disposed;
a step of determining whether the condition is satisfied;
a step of calculating the situation value based on a measured value acquired by a sensing unit; and
a step of outputting the situation value when the condition is satisfied.

### [Item 15]

A computer program for causing an information processing device to perform:
a step of storing a condition for outputting a situation value indicating a state according to a situation in which the information processing device is disposed;
a step of determining whether the condition is satisfied;
a step of calculating the situation value based on a measured value acquired by a sensing unit; and
a step of outputting the situation value when the condition is satisfied.

<System Overview>

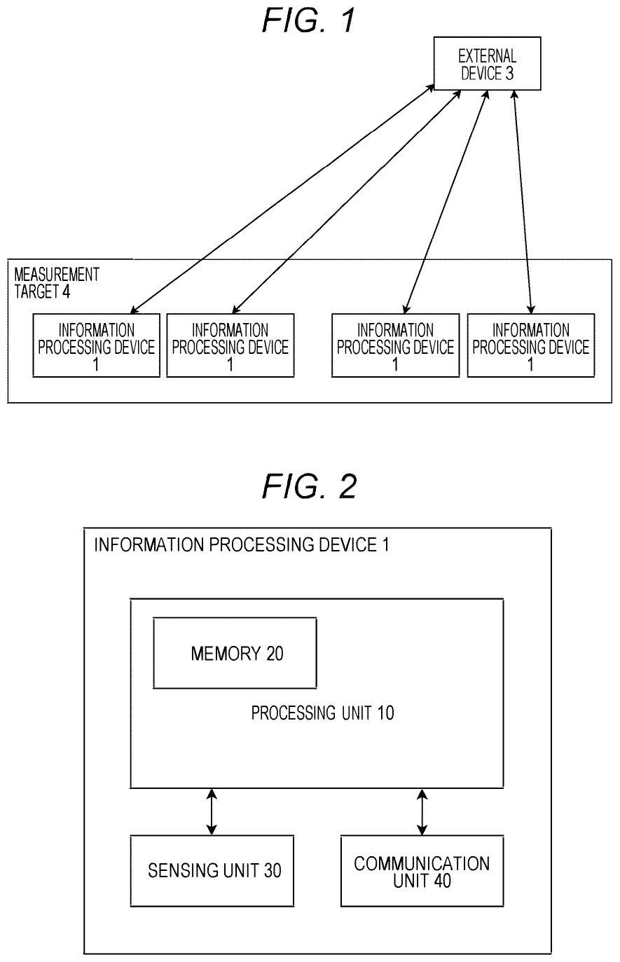

FIG. 1 is a diagram illustrating an example of the overall configuration of an information processing system according to an embodiment of the present invention. The information processing system of the present embodiment includes an information processing device 1. The information processing device 1 is communicably connected to an external device 3 via a communication network. The communication network is, for example, the Internet, and is constructed using a public switched telephone network, a mobile phone network, a wireless communication channel, Ethernet (registered trademark), and the like.

The information processing device 1 is a device that acquires a value (hereinafter, referred to as “situation value”) representing the status of a situation in which the information processing device 1 is disposed. The information processing device 1 is disposed inside a measurement target 4 and can measure the state of the measurement target 4 (for example, temperature, vibration, pressure, electromagnetic waves, volume, humidity, and the like). The measurement target 4 may be, for example, fill, concrete, and the like, or may be water, air, and the like. The information processing device 1 can calculate a situation value by processing a value (hereinafter, referred to as “measured value”) measured by a sensor by using a software algorithm (logic), and output the situation value in response to a request from the external device 3.

The external device 3 is a computer using the situation value acquired from the information processing device 1. What is called an end-user can perform analysis and the like on the situation value acquired by the external device 3 from the information processing device 1.

<Hardware>

FIG. 2 illustrates an example of the hardware configuration of the information processing device 1 that is an embodiment of the present invention. The information processing device 1 includes a processing unit 10 and a sensing unit 30, and the processing unit 10 includes a memory 20. At least a part of the memory 20 includes a nonvolatile storage device and can store a computer program to be executed by the processing unit 10.

The sensing unit 30 measures a measured value according to a situation in which the information processing device 1 is deployed.

The processing unit 10 can receive the measured value measured by the sensing unit 30, record the received value in the memory 20, and calculate a situation value by giving the measured value to a calculation logic. The situation value is a value indicating the state of the situation in which the information processing device 1 is deployed. The processing unit 10 records the calculated situation value in the memory 20.

The present embodiment describes an embodiment in which a coil 30 is applied as an example of the sensing unit; however, the present invention is not limited thereto. The coil 30 can transmit and receive signals, by inductive coupling or other communication methods, to and from a coil 30 of another information processing device disposed adjacent to the information processing device 1. In the present embodiment, information processing devices are used in pairs. As a relative distance or angle between coils of two information processing devices is changed, the coupling strength of inductive coupling is changed and a value of a voltage generated in the coil or an amplitude value of the voltage is changed. In the present embodiment, the processing unit 10 can calculate a situation value by using this voltage as a measured value. The memory 20 can temporarily record the calculated situation value.

A communication unit 40 can communicate with an external device. The communication unit 40 can be implemented by the coil 30, for example. The same coil can be used for the sensing unit 30 and the communication unit to achieve respective functions of the sensing unit 30 and the communication unit 40. That is, the information processing device can output the calculated situation value to the outside of the information processing device via the sensing unit 30, and receive signals including request information to be described later from the outside of the information processing device via the sensing unit 30.

The processing unit 10 and the sensing unit 30 (and the communication unit 40) can be mounted on one board (on one chip) inseparably. In such a case, a diameter of the information processing device 1 can be set to about 0.3 mm.

The information processing device 1 of the present embodiment can store a calculation logic for each of a plurality of types of situation values, and calculate a plurality of types of situation values from the same measured value. By using a calculation logic corresponding to a designated type, the information processing device 1 can obtain different types of situation values based on a measured value of the same sensor (voltage measured by the coil 30).

<Software>

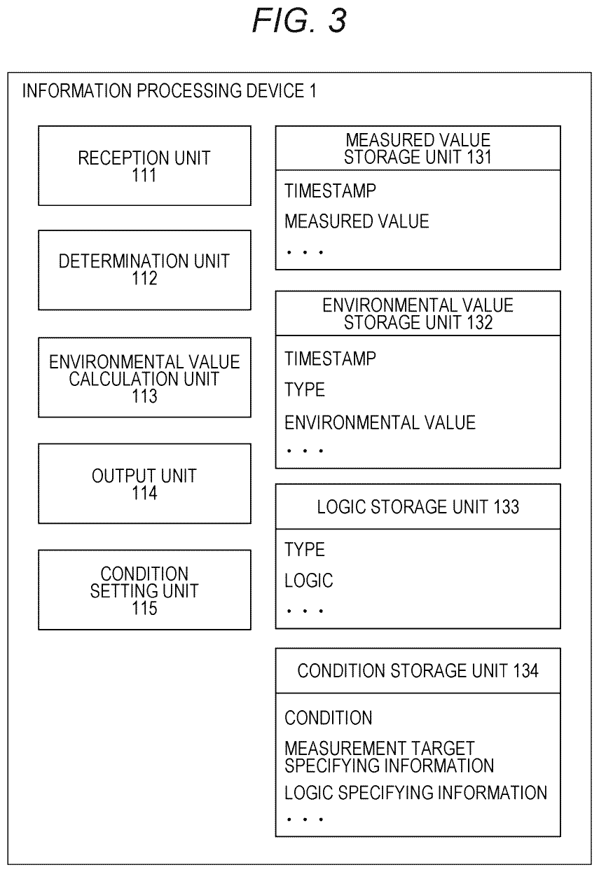

FIG. 3 is a block diagram illustrating the functional configuration of the information processing device 1. The information processing device 1 can include a measured value storage unit 131, a situation value storage unit 132, a logic storage unit 133, a condition storage unit 134, a reception unit 111, a determination unit 112, a situation value calculation unit 113, an output unit 114, and a condition setting unit 115.

The measured value storage unit 131 can store a history of measured values. The measured value storage unit 131 can store measured values by adding timestamps to the measured values. The measured value can be a value output by the sensing unit 30.

The situation value storage unit 132 can store a history of calculated situation values. The situation value storage unit 132 can store situation values by adding timestamps and types of situation values to the situation values. Note that the situation value storage unit 132 may be omitted and the situation values may always be calculated from the measured values.

The logic storage unit 133 can store a logic for calculating observed values based on the measured values. The logic can be, for example, a computer program that can be executed by the processing unit 10.

The condition storage unit 134 can store conditions for outputting the situation values. The condition may be, for example, the presence of an external request. In this case, for example, the situation values can be responded to upon receipt of a request from the external device 3. The condition can also be, for example, the occurrence of an event such as a timer timeout. In this case, the situation values can be output periodically. The condition can also be a condition on the measured values or the situation values. For example, a threshold value for the measured value or the situation value can be set as a condition, and the situation value can be output when the measured value or the situation value is the threshold value or more or less.

In association with the condition, the condition storage unit 134 can store measurement target specifying information that specifies a measured value to be calculated. The measurement target specifying information can be, for example, a range of timestamps. The range of timestamps may be relative to the current point in time, for example. The measurement target specifying information may also be designated as the latest measured value.

The measurement target specifying information may also be information that specifies a situation value. Also in this case, the measurement target specifying information can be, for example, a timestamp of the situation value. The range of timestamps may be relative to the current point in time, for example. The measurement target specifying information may be designated as the latest observed value.

In association with the condition, the condition storage unit 134 may store calculation target specifying information that specifies a measured value to be calculated and logic specifying information that specifies a logic. The logic specifying information can be, for example, the type of situation value. Any information that allows a logic to be specified in the logic storage unit 133 may be used.

The reception unit 111 can receive external requests. For example, the reception unit 111 can receive requests from the external device 3.

The determination unit 112 determines whether the condition is satisfied. The determination unit 112 can, for example, receive an interrupt from some event to verify whether the condition is satisfied for all conditions stored in the condition storage unit 134. The event may be anything that can be captured within the information processing device 1, and, for example, may be a clock, that the reception unit 111 has received a request or that the sensing unit 30 has measured a measured value.

The situation value calculation unit 113 can calculate the situation values based on the measured values. In the present embodiment, the situation value calculation unit 113 can calculate the situation values by giving the measured values to the logic stored in the logic storage unit 133. When a plurality of logics are registered in the logic storage unit 133, the situation value calculation unit 113 can be configured to calculate a plurality of types of situation values by using the logics. When the determination unit 112 determines that the condition is satisfied, the situation value calculation unit 113 can calculate situation values.

The situation value calculation unit 113 can also calculate the situation values by using the measured values stored in the measured value storage unit 131. Note that the situation value calculation unit 113 may be given the measured values acquired from the sensing unit 30 to calculate the situation values.

The situation value calculation unit 113 may calculate the situation values based on one measured value, or calculate the situation values based on a plurality of measured values (history). In this case, one measured value may be the latest measured value (instantaneous value) acquired by the sensing unit 30, or one of the measured values stored in the measured value storage unit 131 may be read out.

The situation value calculation unit 113 may also be configured to calculate the situation values based on a first measured value corresponding to a first period and a second measured value corresponding to a second period having a length different from a length of the first period. For example, the situation value calculation unit 113 can be a logic to calculate the situation values based on measured values for one day and measured values for one week.

The situation value calculation unit 113 can also calculate the situation values by using externally designated measured values. For example, when a timestamp period is designated in the request received by the reception unit 111, the situation value calculation unit 113 can read measured values corresponding to the timestamp included in the period designated in the request from the measured values, and calculate the situation values based on the read measured values.

In this case, the situation value calculation unit 113 can calculate the situation values by using measured values for a sampling cycle corresponding to the designated period. The sensing unit 30 may measure measured values at different cycles and record the measured values for each cycle in the measured value storage unit 131, or measured values measured at the shortest sampling cycle may be recorded in the measured value storage unit 131 and the situation value calculation unit 113 may extract measured values at the cycle corresponding to the designated period from the measured value storage unit 131. For example, in the case of a logic that analyzes long-term trends, long-cycle (sparse) measured values can be used to calculate situation values, and in the case of a logic that performs detailed short-term analysis, short-cycle (dense) measured values can be used to calculate situation values.

The situation value calculation unit 113 may also read measured values specified by calculation target specifying information corresponding to the satisfied condition from the measured value storage unit 131, and calculate the situation values based on the read measured values.

The situation value calculation unit 113 may also calculate the situation values by giving the measured values specified by the calculation target specifying information corresponding to the satisfied condition to a logic specified by logic specifying information corresponding to the satisfied condition.

The output unit 114 can output the situation values. The output unit 114 can output the situation values upon receipt of a request by the reception unit 111. This allows output of what is needed when necessary.

The output unit 114 may also output the situation values when the condition is satisfied. This allows the situation values to be output when the condition is satisfied.

The output unit 114 can read situation values corresponding to a period specified in the request from the situation value storage unit 132, and output the read situation values.

The condition setting unit 115 sets conditions in the condition storage unit 134. The condition setting unit 115 can receive conditions from the external device 3 and set the received conditions in the condition storage unit 134. The condition setting unit 115 can receive new conditions from the external device 3 and add the received conditions to the condition storage unit 134, or may receive information specifying a condition to be updated and the conditions and update specified conditions. Of course, the condition setting unit 115 can also receive the measurement target specifying information and the logic specifying information from the external device 3, and set the received information in the condition storage unit 134 together with the conditions.

<Operation>

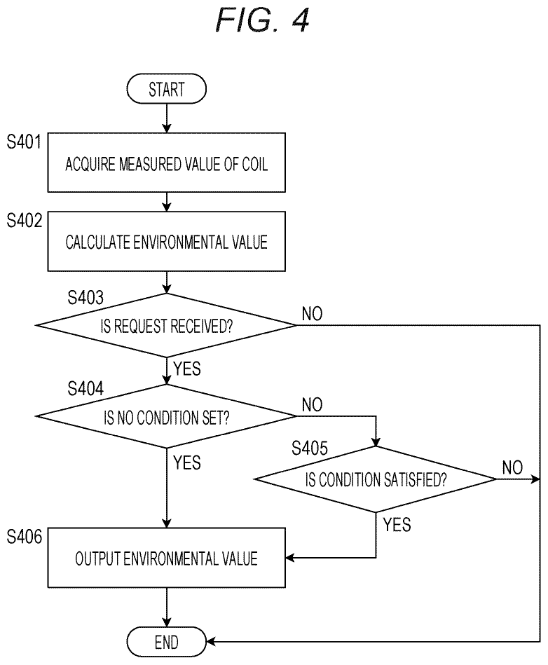

FIG. 4 is a diagram for explaining an operation of the information processing device 1 of the present embodiment.

The information processing device 1 acquires a measured value by the sensing unit 30 (coil) (S401), and applies a logic to the acquired measured value to calculate a situation value (S402). In a case in which the information processing device 1 receives a request from the external device 3 (S403: YES), when a condition is set (S404: NO), the information processing device 1 can output the situation value (S406) when the condition is satisfied (S405: YES).

As described above, the information processing device 1 of the present embodiment can output situation values in response to external requests, so that the external device 3 can acquire what is needed when necessary. The information processing device 1 of the present embodiment can set a condition and output the situation values when the condition is satisfied.

Although the present embodiment has been described above, the above embodiment is for facilitating the understanding of the present invention and is not intended to be interpreted as limiting the present invention. The present invention can be changed and improved without departing from the spirit thereof, and also includes equivalents thereof.

For example, although FIG. 4 assumes that a request is received, situation values can be automatically transmitted from the information processing device 1 to the external device 3 when a condition is satisfied, even though no request is received.

### REFERENCE SIGNS LIST

1 Information processing device
3 External device
4 Measurement target

1. An information processing device comprising:
a processing unit including a memory;
a sensing unit including a coil and configured to acquire, as a measured value, a value of a voltage generated in the coil or an amplitude value of the voltage;
a condition storage unit configured to store a condition for outputting a situation value indicating a state according to a situation in which the information processing device is disposed;
a determination unit configured to determine whether the condition is satisfied;
a situation value calculation unit configured to calculate the situation value based on the measured value acquired by the sensing unit; and
an output unit configured to output the situation value to outside of the information processing device via the coil when the condition is satisfied.

2. The information processing device according to claim 1, further comprising
a condition setting unit configured to receive the condition from the outside of the information processing device via the coil, and to set the condition in the condition storage unit.

3. The information processing device according to claim 1, further comprising
a measured value storage unit configured to store a history of the measured value, wherein
the situation value calculation unit reads the measured value from the measured value storage unit, and calculates the situation value based on the read measured value.

4. The information processing device according to claim 3, wherein the situation value calculation unit calculates the situation value based on a first measured value corresponding to a first period and a second measured value corresponding to a second period having a length different from a length of the first period.

5. The information processing device according to claim 1, wherein
the sensing unit measures a first measured value at a first cycle and measures a second measured value at a second cycle shorter than the first cycle, and
the situation value calculation unit calculates the situation value based on the first and second measured values.

6. The information processing device according to claim 1, further comprising:
a situation value storage unit configured to store a history of the calculated situation value; and
a reception unit configured to receive an external request, wherein
the output unit reads the situation value corresponding to a period designated in the request from the situation value storage unit, and outputs the read situation value.

7. The information processing device according to claim 6, wherein
the situation value calculation unit calculates a second situation value based on the measured value acquired by the sensing unit and a first situation value stored in the situation value storage unit, and
the output unit outputs the second situation value.

8. The information processing device according to claim 1, further comprising:
a measured value storage unit configured to store a history of the measured value; and
a reception unit configured to receive a request from the outside of the information processing device via the coil, wherein
the situation value calculation unit reads the measured value corresponding to a period designated in the request from the measured value storage unit, and calculates the situation value based on the read measured value.

9. The information processing device according to claim 8, wherein the situation value calculation unit extracts the measured value at different cycles depending on a length of the period from the measured value storage unit, and calculates the situation value based on the extracted measured value.

10. The information processing device according to claim 1, wherein
the condition storage unit stores specifying information that specifies the measured value to be calculated in association with the condition, and
the information processing device further comprises:
a measured value storage unit configured to store a history of the measured value; and
a situation value calculation unit configured to read the measured value specified by the specifying information corresponding to the satisfied condition from the measured value storage unit, and to calculate the situation value based on the read measured value.

11. The information processing device according to claim 1, further comprising:
a logic storage unit configured to store a logic for calculating the situation value based on the measured value, wherein
the condition storage unit stores, in association with the condition, calculation target specifying information that specifies the measured value to be calculated and logic specifying information that specifies the logic, and
the information processing device further comprises:
a measured value storage unit configured to store a history of the measured value; and
a situation value calculation unit configured to calculate the situation value by giving the measured value specified by the calculation target specifying information corresponding to the satisfied condition to the logic specified by the logic specifying information corresponding to the satisfied condition.

12. The information processing device according to claim 1, wherein a signal is received from the outside of the information processing device via the sensing unit.

13. An information processing method performed by an information processing device including a processing unit including a memory and a sensing unit including a coil and configured to acquire, as a measured value, a value of a voltage generated in the coil or an amplitude value of the voltage, the information processing method comprising:
a step of storing a condition for outputting a situation value indicating a state according to a situation in which the information processing device is disposed;
a step of determining whether the condition is satisfied;
a step of calculating the situation value based on the measured value acquired by the sensing unit; and
a step of outputting the situation value to outside of the information processing device via the coil when the condition is satisfied.

14. A non-transitory computer readable recording medium recording a computer program for causing an information processing device including a processing unit including a memory and a sensing unit including a coil and configured to acquire, as a measured value, a value of a voltage generated in the coil or an amplitude value of the voltage to perform:
a step of storing a condition for outputting a situation value indicating a state according to a situation in which the information processing device is disposed;
a step of determining whether the condition is satisfied;
a step of calculating the situation value based on the measured value acquired by the sensing unit; and
a step of outputting the situation value to outside of the information processing device via the coil when the condition is satisfied.
